(19) United States
(12) Patent Application Publication
(10) Pub. No.: US 2017/0082662 A1
(43) Pub. Date: Mar. 23, 2017

(54) MODULE WITH INTEGRAL SENSOR

(71) Applicant: Molex, LLC, Lisle, IL (US)

(72) Inventors: Marko Spiegel, LaFox, IL (US); Daniel G. ACHAMMER, Warrenville, IL (US)

(73) Assignee: Molex, LLC `, Lisle, IL (US)

(21) Appl. No.: 15/309,130

(22) PCT Filed: May 6, 2015
(86) PCT No.: PCT/US2015/029364

§ 371 Date: Nov. 4, 2016

Related U.S. Application Data
(60) Provisional application No. 61/988,970, filed on May 6, 2014.

(51) Int. Cl. G01R 15/20

(52) U.S. Cl. CPC G01R 15/207; G01R 15/202

(57) ABSTRACT

A module includes a concentrator with a gap and a central opening, a sensor secured in a gap in the concentrator and a power conduit extending through the central opening. Conductors extend from the sensor to provide results from the sensor. The sensor can be configured to measure flux generated by the concentrator. The power conduit is electrically isolated from and mechanically coupled to the concentrator.

### RELATED APPLICATIONS

This application claims priority to U.S. Provisional Application No. 61/988,970, filed May 6, 2014, which is incorporated herein by reference in its entirety.

### TECHNICAL FIELD

This disclosure relates to the field of sensors, more specifically to the field of sensors for power applications.

### DESCRIPTION OF RELATED ART

In many applications it is desirable to monitor the current flowing through a conductor. While older systems would often use large oversized conductors to manage potential current spikes, the desire to improve efficiency and reduce weight and costs have made it more desirable to use power handling systems that have a reduced safety factor. To help protect against current spikes that might cause overheating, current sensors can be provided so as to provide a feedback mechanism that can be used to trigger the appropriate controls. Examples of known current sensors are depicted in FIGS. 1-3. As can be appreciated, the sensors include a plastic body that houses a sensor (which can be a Hall-effect sensor or other known current sensor) and the sensors are mounted around conductors (typically insulated conductors), as is depicted in FIGS. 4-5. The sensors include wires that extend from a body of the sensor and the wires deliver signals to a control system. While the depicted systems are effective, the existing sensors tend take up a fair amount of space and there is a concern that the sensor may inadvertently wear away the protection insulative covering, potentially exposing a conductor that would be considered quite dangerous due to voltage and current loads. While it would be useful to shrink the size of current sensors, the desire to provide good saturation resistance and the mechanical properties of silicon steel (which is what is used as the metal for concentrators) makes it difficult to provide an improved solution. However, certain individuals would appreciate further improvements in a sensor.

### SUMMARY

A module is disclosed that includes a sensor that is integrated into the module. The depicted design can be used to provide current sensing with known types of sensors while substantially reducing the packaging space needed for the sensor. In an embodiment, a housing is provided that includes a power duct. The power duct includes an aperture and can be configured to act as a washer or as a terminal. A sensor is supported by the housing and is positioned adjacent the power duct between a split in a field concentrator and is used to sense the current flowing through the power duct.

### BRIEF DESCRIPTION OF THE DRAWINGS

The present invention is illustrated by way of example and not limited in the accompanying figures in which like reference numerals indicate similar elements and in which:

FIG. 1 illustrates an embodiment of a prior art sensor.

FIG. 2 illustrates an embodiment of a prior art sensor.

FIG. 3 illustrates an embodiment of a prior art sensor.

FIG. 4 illustrates an embodiment of a prior art sensor in an installed position.

FIG. 5 illustrates an embodiment of a prior art sensor in an un-installed and installed position.

FIG. 6 illustrates an embodiment of a module with an integral sensor.

FIG. 7 illustrates a partially exploded view attic embodiment depicted in FIG. 6.

FIG. 8 illustrates a perspective view of an embodiment of a module with integral sensor.

FIG. 9 illustrates a perspective view of another embodiment of a module with an integral sensor.

FIG. 10 illustrates another perspective view of the embodiment depicted in FIG. 9.

FIG. 11 illustrates a partially exploded perspective view of the embodiment depicted in FIG. 9.

FIG. 12 illustrates another perspective view of the embodiment depicted in FIG. 11.

FIG. 13 illustrates a perspective view of a portion of the module depicted in FIG. 9.

FIG. 14 illustrates a partially exploded perspective view of the embodiment depicted in FIG. 13.

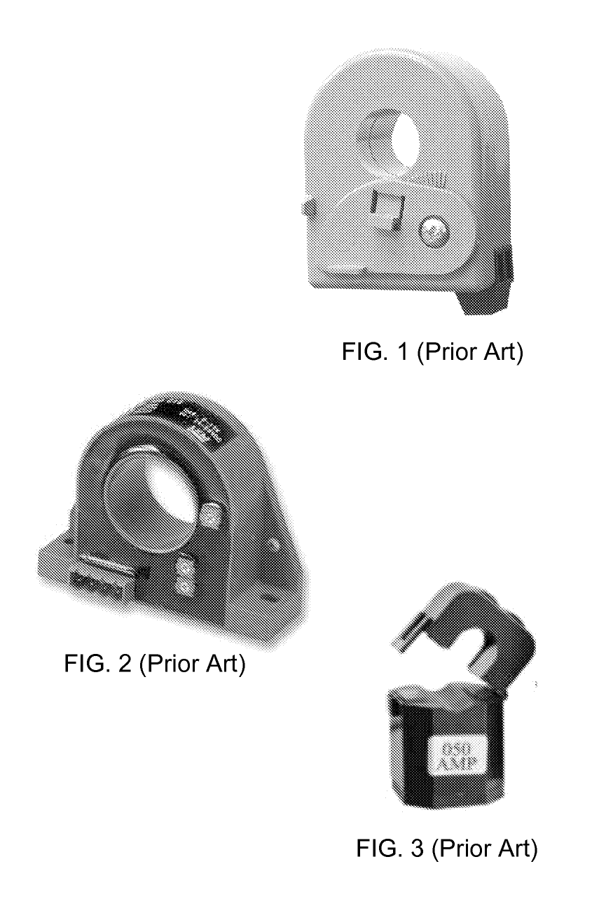

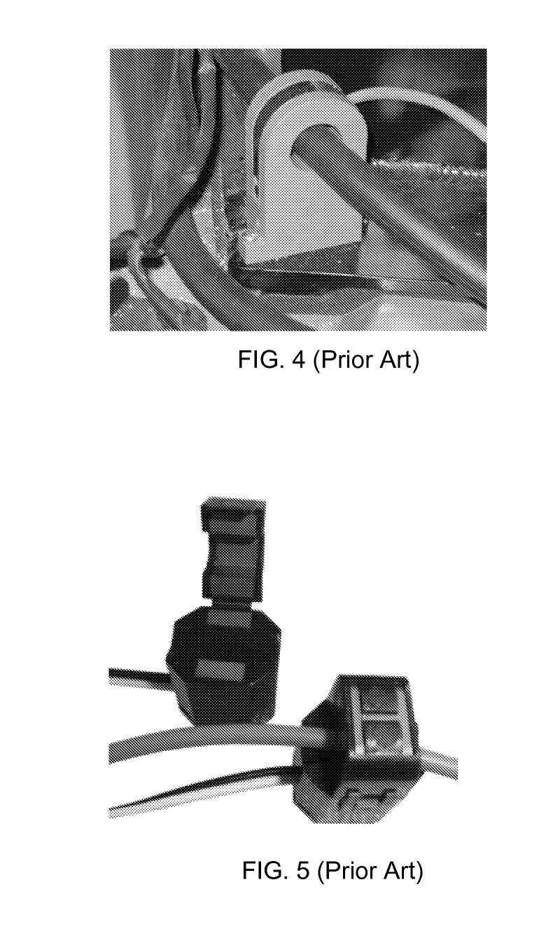

### DETAILED DESCRIPTION

The detailed description that follows describes exemplary embodiments and is not intended to be limited to the expressly disclosed combination(s). Therefore, unless otherwise noted, features disclosed herein may be combined together to form additional combinations that were not otherwise shown for purposes of brevity.

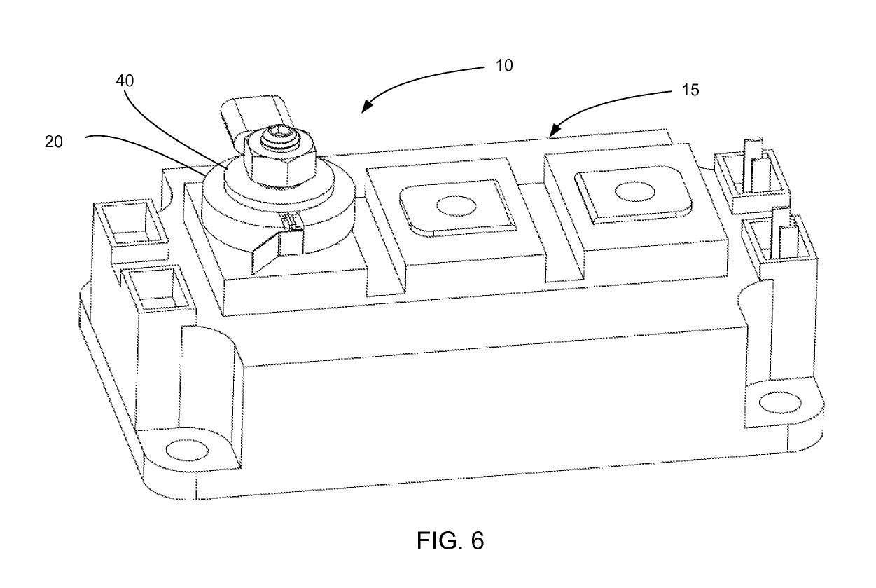

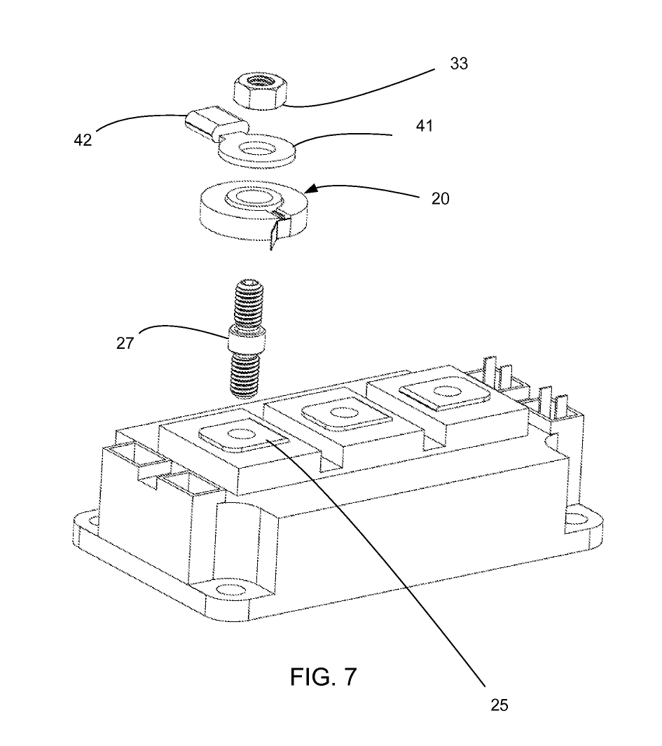

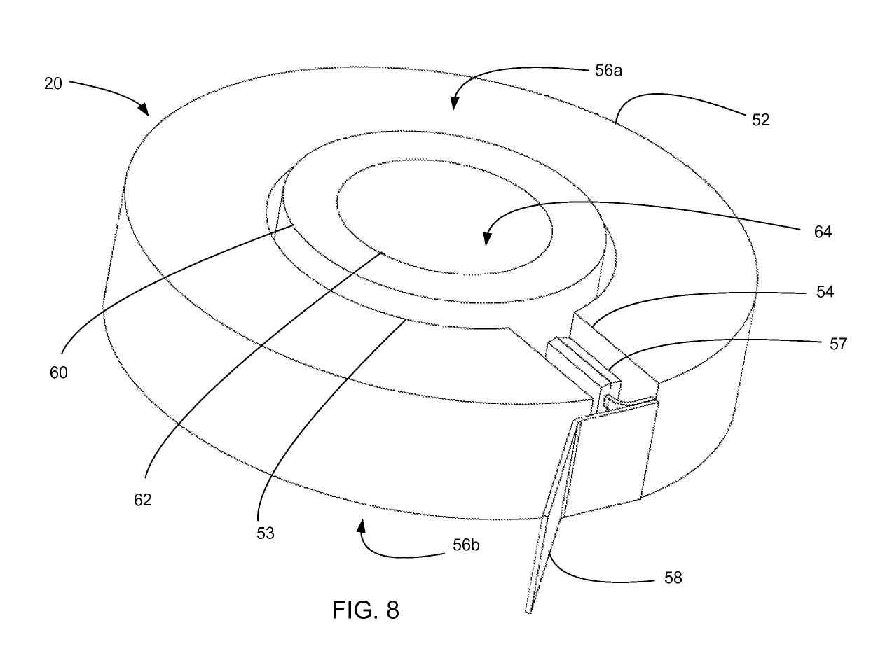

FIGS. 6-8 illustrate features of an embodiment of system that can be provided to measure and/or sense current flowing through a conductor so as to provide feedback in a desirable manner. A system 10 includes a base 15 that includes 1 or more power ports 25 (which can be in the form conventionally used with IGBTs). A module 20 is provided between a conductor 40 and the power port 25 in the base 15. A threaded bolt 27 can be mounted in the power port 25 and a nut 33 is used to press a flat head 41 against the module 20.

As can be appreciated, the module 20 includes a field concentrator 52 with a gap 54 sized to provide the desired flux. The field concentrator 52 can be formed of amorphous alloy and have a cross-section with a desired shape and includes opposing sides 56a, 56b. A power conduit 60 is provided inside of the field concentrator 52 and extends past the opposing sides 56a, 56b and the power conduit 60 is electrically isolated from the field concentrator. A sensing unit includes a sensor 57 connected to conductor 58 and the sensor 57 can be adhered into position in the gap 54. In practice, the power conduit 60, which includes an inner surface 62, defines a channel 64 that extends beyond opposing sides of the concentrator 52 so that current going through the power conduit 60 (either directly and/or through the channel) creates a flux in the concentrator that is detected by the sensor 57. The channel 64 provides a place for the threaded bolt to be positioned and the power conduit provides an electrical path with low resistance (the power conduit 60 can be a copper alloy) between the power port 25 and the conductor 40/flat head 41.

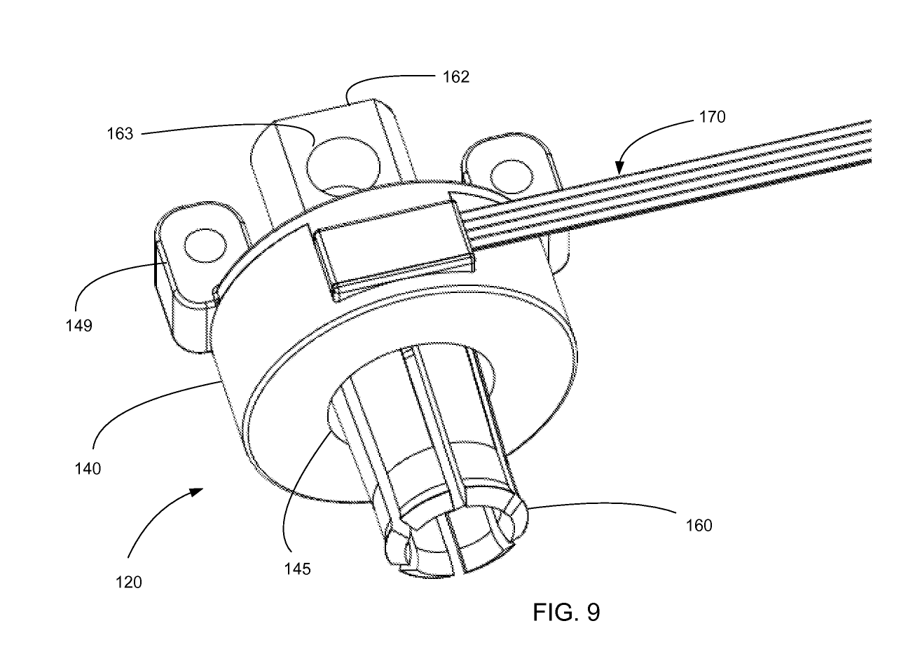

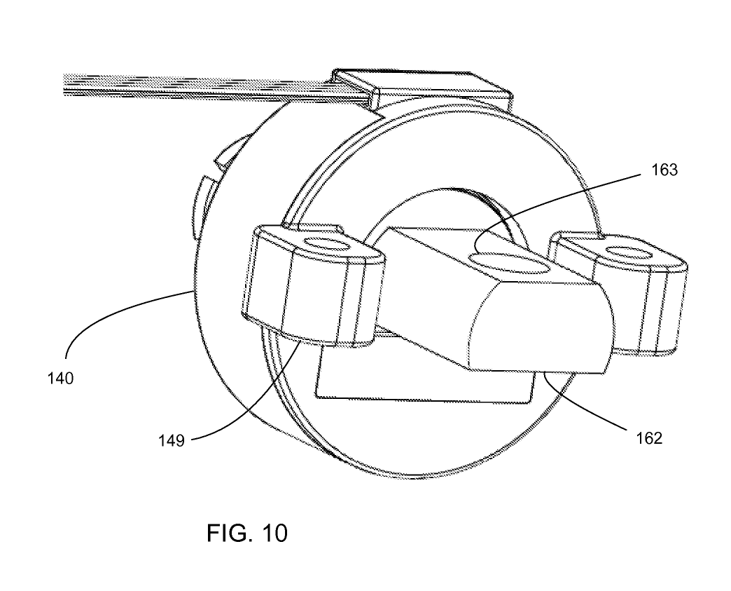

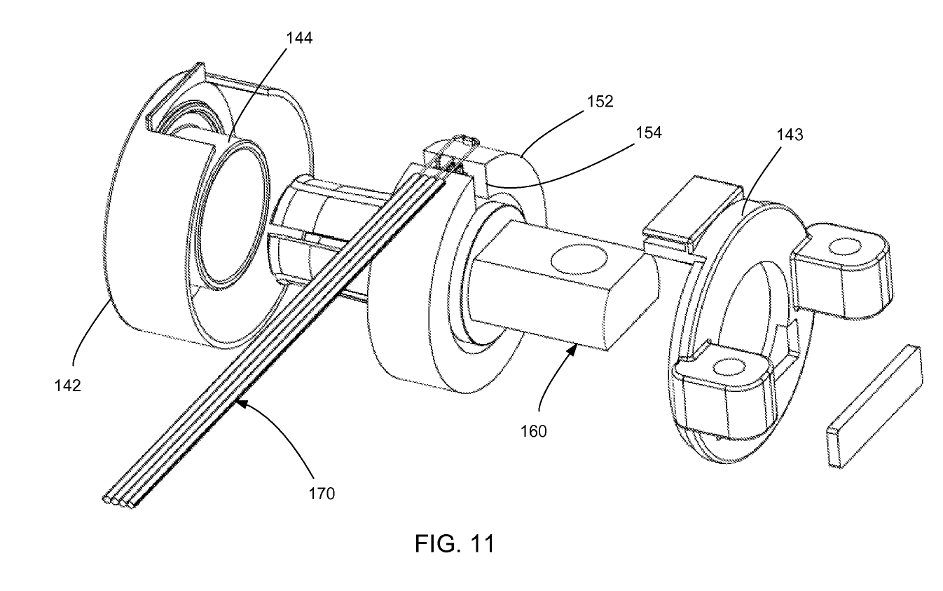

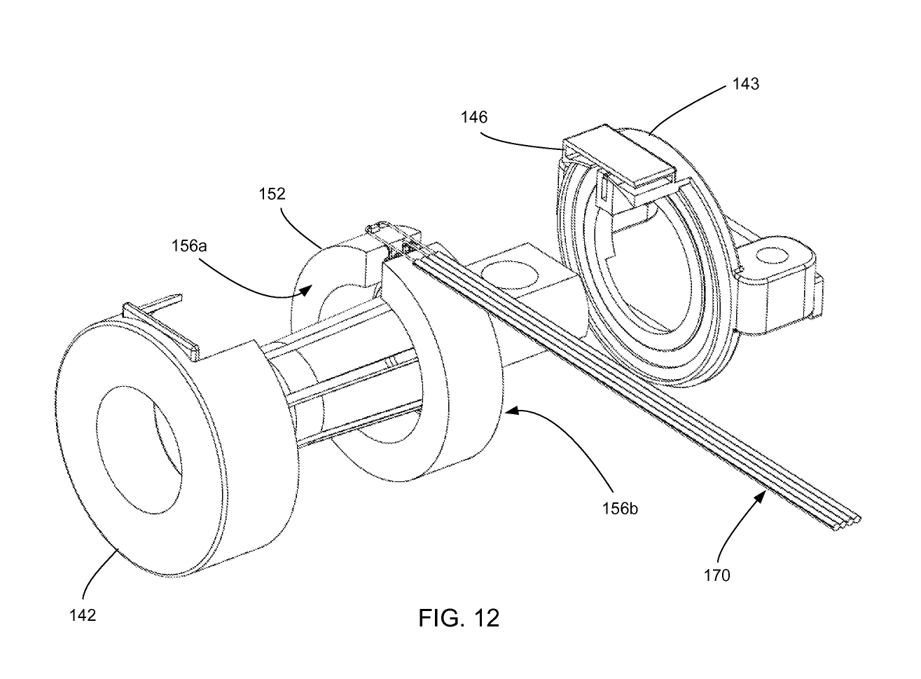

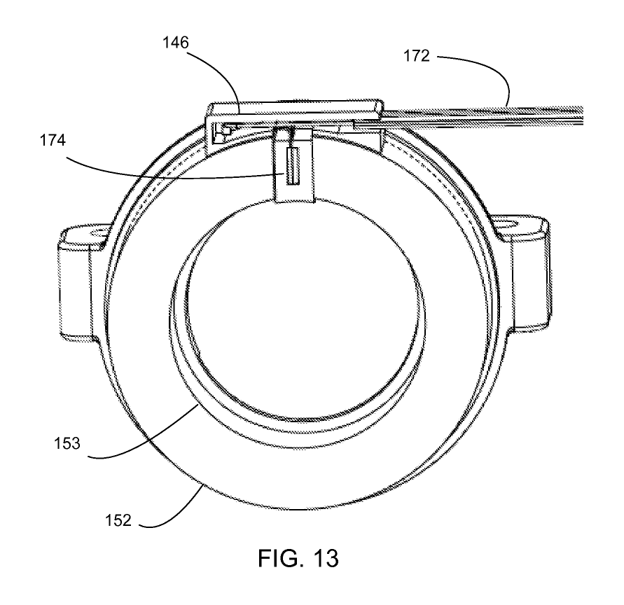

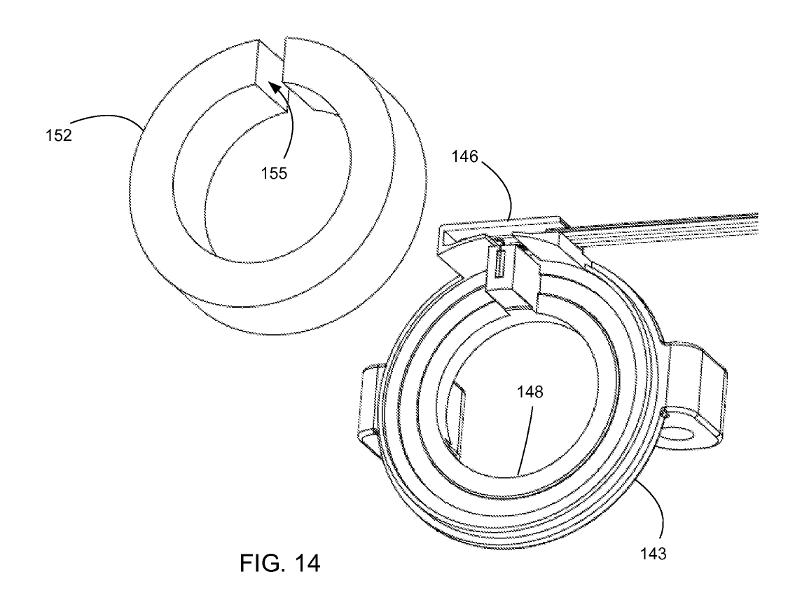

FIGS. 9-14 illustrate features of an embodiment of a module 120. The module 120 includes a housing 140 with an aperture 145 and a power conduit 160 is positioned in the aperture 145 and extends through central opening 153 of concentrator 152 past opposing faces 156a, 1156b of the concentrator 152. The housing 140 helps provide electrical isolation between concentrator 152 and the power conduit 160. To help provide electrical isolation, the housing 140 includes an inner wall 144 that extends between the power conduit 160 and the concentrator 152. The housing can include lugs 149 that can be used to help secure the housing 140 in a desired position.

The power conduit 160 is shaped with multiple contacts that can mate to cylinder-shaped terminal and includes a clamping section 162 with an aperture 163 that is intended to help allow the power conduit 160 to be secured with a fastener to a power port (not shown). As can be appreciated, however, the power conduit 160 could be configured to mate with a different shaped terminal and thus the depicted design is not intended to be limiting unless otherwise noted.

The housing 140 includes a first portion 142 (which includes the inner wall 144) and a second portion 143 with a base 148 that supports the concentrator 152 and the second portion 143 includes a sensor support 146. The sensor support 146 supports a sensing unit 170 that includes conductors 172 and a sensor 174 that is intended to be positioned in a gap 155 of concentrator 152. Sensors are well known and a variety of manufactures provide suitable sensors that can be in the form of a hall-effect sensors but can also be other types of sensors, thus further discussion of the sensor is not required herein.

In operation, the power conduit 160 provides a low resistance path through the housing 140 that allows for a sensing unit (which could be based on hall-effect sensor or other suitable sensing technology) to detect the amount of current flowing through the power conduit without taking up a significant amount of space. Thus, the depicted embodiments allow for sensing of power in a manner that can place the sensor closer to a device that is using or providing the power (which can be useful from a control standpoint). In addition, the sensing unit can (depending on the type of sensing chip used) also be used to detect thermal rise if desired.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

We claim:

1. A module, comprising:
a concentrator formed of an amorphous alloy, the concentrator having a gap sized to provide a desired level of flux and a central opening;
a sensor securely position in the gap, the sensor configured to sense flux variations;
conductors extending from the sensor; and
a power conduit extending through the central opening, the power conduit electrically isolated from the concentrator and mechanically coupled to the concentrator, wherein, in operation, current flowing through the power conduit creates a flux variation that is sensed by the sensor.

2. The module of claim 1, further comprising a housing that supports the concentrator and the power conduit.

3. The module of claim 2, wherein the housing includes an inner wall that extends between the concentrator and the power conduit.

4. The module of claim 3, wherein the housing includes a sensor support that is configured to position the sensor in the gap.

5. The module of claim 4, wherein the housing includes lugs configured to support the housing.
